(19) United States
(12) Patent Application Publication
(10) Pub. No.: US 2025/0125167 A1
(43) Pub. Date: Apr. 17, 2025

(54) MONITORING APPARATUS FOR PACKAGE

(71) Applicant: SAMSUNG ELECTRONICS CO., LTD., Suwon-si (KR)

(72) Inventor: Minyan WU, Suzhou (CN)

(73) Assignees: SAMSUNG ELECTRONICS CO., LTD., Suwon-si (KR); Samsung Semiconductor China Research & Development Co., LTD., Suzhou (CN)

(21) Appl. No.: 18/643,725

(22) Filed: Apr. 23, 2024

(30) Foreign Application Priority Data
Oct. 11, 2023 (CN) 202311315338.1

(51) Int. Cl. H01L 21/67; G05B 19/048

(52) U.S. Cl. CPC H01L 21/67144; G05B 19/048; H01L 21/67253; G05B 2219/37399; G05B 2219/45031

(57) ABSTRACT

A monitoring apparatus for a package includes a pressure applying device configured to apply a pressure to the package, a sensor configured to measure the pressure applied to the package by the pressure applying device, and a signal transmitting apparatus electrically coupled to the package and configured to input an input signal to a chip of the package, receive an output signal from the package in real time, and monitor a damage of the chip of the package in real time while the pressure applying device applies the pressure to the package.

### CROSS-REFERENCE TO RELATED APPLICATIONS

This application claims benefit of priority under 35 U.S.C. § 119 to Chinese Patent Application No. 202311315338.1, filed on Oct. 11, 2023, in the China National Intellectual Property Administration, the disclosure of which is incorporated by reference herein in its entirety.

### BACKGROUND

### 1. Field

The present disclosure relates generally to a monitoring apparatus for a package, and more particularly, to a package strength monitoring apparatus for monitoring functional failure of the package in real time.

### 2. Description of Related Art

Recently, as demand increases for increased chip integration densities and/or reduced chip sizes, design constraints for packaging of the chips may also increase. Consequently, with the increasing importance of the chip packaging, randomly selected packages comprising installed chips may be subjected to impact and/or drop tests to test for packaging errors and/or faults. For example, tests designed to quantify the strength of a chip package may include, but not be limited to, three-point bend testing (3PB), four-point bend testing (4PB), impact testing, drop testing, and the like. Typically, such tests may determine the strength of the package based on fracture values.

However, the internal structure of the package may be complex, and as such, a functional failure of the package may occur earlier (e.g., a lower fracture value) than a fracture failure of the package. Thus, in order to determine the strength threshold of the package based on a functional failure of the package, related approaches may include to repeatedly conduct a static and/or dynamic mechanical test on the package, and after each test iteration, perform a functional test of the package and reduce the test load for the next iteration, until the functional failure threshold of the package is determined.

However, the related approaches may not be able to monitor chip damage that may occur during testing. Consequently, determining the functional failure threshold may require performing a large number of test iterations and adjusting the test load between each test iterations. In addition, the related approaches may not be able to determine whether the test failure is caused by the strength testing and/or the functional testing, which may lead to erroneous results.

Thus, there exists a need for further improvements in package strength testing, as the need for increased chip integration densities and/or reduced chip sizes may be constrained by erroneous functional failure threshold determinations of packages. Improvements are presented herein. These improvements may also be applicable to other semiconductor and packaging technologies.

### SUMMARY

One or more example embodiments of the present disclosure provide a monitoring apparatus for a package, which may monitor the standby current, and the like, of a chip inside the package in real time by applying pressure to the package without moving the package, so as to determine whether the function of the chip has been damaged. Further, one or more example embodiments of the present disclosure provide for, in the monitoring apparatus and by using the high pressure gas, to conduct static and/or dynamic mechanical testing on the package, and monitor the chip damage and failure inside the package in real time, thereby obtaining an accurate package strength value based on functional failure.

According to an aspect of the present disclosure, a monitoring apparatus for a package includes a pressure applying device configured to apply a pressure to the package, a sensor configured to measure the pressure applied to the package by the pressure applying device, and a signal transmitting apparatus electrically coupled to the package and configured to input an input signal to a chip of the package, receive an output signal from the package in real time, and monitor a damage of the chip of the package in real time while the pressure applying device applies the pressure to the package.

In some embodiments, the monitoring apparatus may include a strainmeter disposed on a lower surface of the package and configured to measure a strain value of the package.

In some embodiments, the pressure applying device may include a conduit and a gas generating device configured to provide a high pressure gas. A first end of the conduit may be coupled to the gas generating device and configured to transmit the high pressure gas.

In some embodiments, the monitoring apparatus may include an accommodation box configured to accommodate the package. A surface of the accommodation box may include a guide rail. The pressure applying device may include a movable carrier stage. The movable carrier stage may be movable along the guide rail of the accommodation box, and the conduit may pass through the movable carrier stage.

In some embodiments, the pressure applying device may include a flexible pipe. A second end of the conduit may be coupled to an end of the flexible pipe in a direction-changeable and interconnected manner.

In some embodiments, the conduit may be coupled to the flexible pipe through a spherical hinge support.

In some embodiments, the gas generating device may include a gas storage device configured to store the high pressure gas.

In some embodiments, the gas storage device may include an electromagnetic valve.

In some embodiments, the gas generating device may include a cylinder, an intake port disposed on an upper surface of the cylinder, an exhaust port disposed on a lower surface of the cylinder, and a piston disposed in the cylinder and configured to compress a gas in the cylinder.

In some embodiments, the gas generating device may be configured provide an external gas enters into a cavity of the cylinder through the intake port, compress the external gas via a reciprocating motion of the piston, and discharge compressed gas out of the cylinder from the exhaust port, to enter into the conduit.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a schematic diagram illustrating a monitoring apparatus for monitoring a strength of a package statically in real time, according to an exemplary embodiment of the present disclosure;

FIG. 2 is a schematic diagram illustrating a monitoring apparatus for monitoring a threshold of functional failure of a package dynamically in real time, according to an exemplary embodiment of the present disclosure; and

FIG. 3 is a schematic diagram illustrating a monitoring apparatus for monitoring a threshold of functional failure of a package dynamically in real time, according to another exemplary embodiment of the present disclosure.

### DETAILED DESCRIPTION

Embodiments of the present disclosure are described with reference to the accompanying drawings in which exemplary embodiments of the present disclosure are illustrated. However, the present disclosure may be implemented in many different forms, and may not be constructed as being limited to the embodiments set forth herein. Rather, these embodiments are provided so that the present disclosure is thorough and complete, and may convey the concept of the present disclosure to those of ordinary skill in the art. In the following detailed description, numerous specific details may be set forth by way of examples, to provide a full understanding for relevant teachings. However, it may be understood by those skilled in the art that the present disclosure may be practiced without such details. In other cases, well-known methods, steps, and components may be described at a relatively high level without details, to avoid unnecessarily obscuring multiple aspects of the present teaching. Like reference numerals may denote like elements in the drawings, and thus, descriptions thereof may not be repeated. In the drawings, sizes and relative sizes of a layer and an area may be exaggerated for clarity.

Spatially relative terms, such as, but not limited to, “beneath”, “below”, “lower”, “under”, “above,” “upper” and the like, may be used herein for ease of explanation to describe one element or feature's relationship to another element and/or feature as illustrated in the drawings. It may be understood that the spatially relative terms may be intended to encompass different orientations of the device in use and/or in operation, in addition to the orientation depicted in the figures. For example, if the device in the drawings is turned over, elements described as “below”, “beneath” or “under” other elements or features would then be oriented “above” the other elements or features. Thus, the example terms “below” and “under” may encompass both an orientation of above and below.

As used herein, the phrase “on a plane” and/or “a plan view” may refer to an object portion being viewed from the top, and the phrase “in a cross-sectional view” may refer to viewing, from the side, a cross-section taken by vertically cutting an object portion. In addition, the phrase “vertical direction” may indicate upper and lower directions in the cross-sectional view.

As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like. Hereinafter, various embodiments of the present disclosure are described with reference to the accompanying drawings.

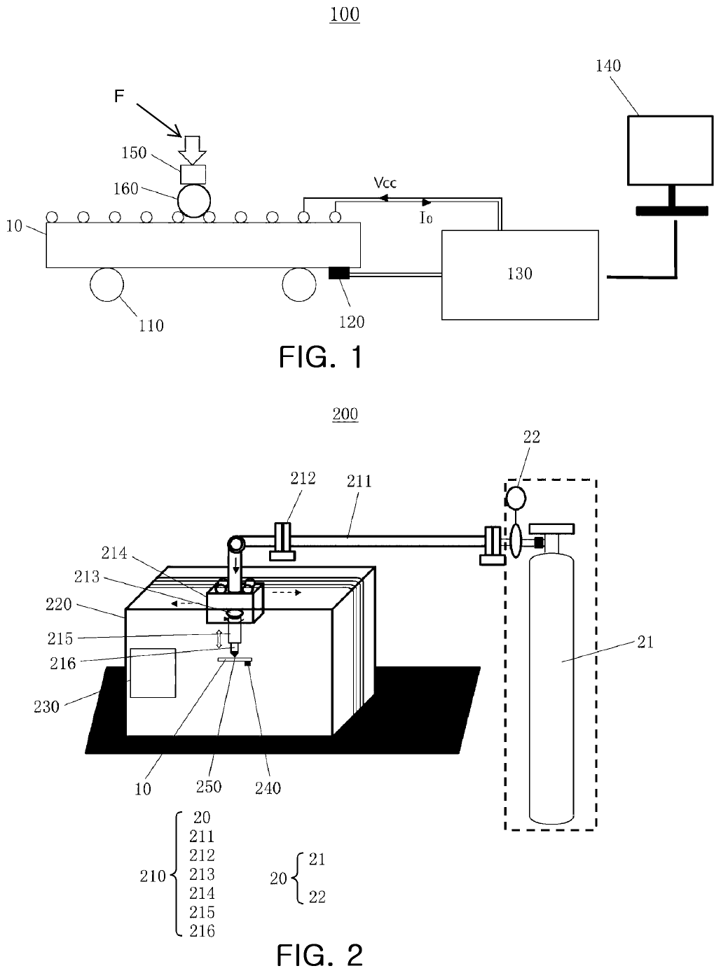

FIG. 1 is a schematic diagram illustrating a monitoring apparatus for monitoring a strength of a package statically in real time, according to an exemplary embodiment of the present disclosure.

Referring to FIG. 1, a static monitoring apparatus 100 may include a support member 110, a strainmeter 120, a signal transmitting apparatus 130, a monitor 140, a load sensor 150 (also referred to as sensor), and a pressure head 160. A package 10 may be disposed on the support member 110 of the static monitoring apparatus 100. The package 10 may be and/or may include a package in which chips are packaged.

The strainmeter 120 may be disposed on a bottom surface of the package 10, to measure a strain value of the package 10, and may collect the strain value of the surface of the package 10 during testing. Although FIG. 1 illustrates the strainmeter 120 as being disposed at an edge of the bottom surface of the package 10, the position of the strainmeter 120 may not be limited thereto. In an exemplary embodiment, the strainmeter 120 may be disposed at another position of the package 10.

The signal transmitting apparatus 130 may be configured to be electrically connected (e.g., coupled) to the package 10, so as to monitor a damage of the chip inside the package 10 in real time while the pressure applying device applies the pressure to the package 10. The signal transmitting apparatus 130 may input a certain (e.g., input) signal to the chip of the package 10, and receive an output signal from the package 10 in real time. The input signal may be and/or may include a voltage and/or a segment of codes. In an exemplary embodiment, the signal transmitting apparatus 130 may apply a voltage Vcc to the package 10. For example, the signal transmitting apparatus 130 may be electrically connected (e.g., coupled) to a solder ball of the package 10 to apply the voltage Vcc to the package 10 in real time, and receive a monitoring current I₀ from the package 10 in real time during testing. The monitoring current I₀ may be and/or may include a standby current of the package 10. The signal transmitting apparatus 130 may be electrically connected (e.g., coupled) to different solder balls of the package 10, to monitor currents at different positions, thereby realizing the effect of real-time spot detecting the particular chip inside the package 10. That is, the signal transmitting apparatus 130 may monitor the standby currents of one or more chips of the package 10 in real time by being electrically connected (e.g., coupled) to different solder balls of the package 10, and thereby monitoring damage of the chip inside the package 10.

In an embodiment, the signal transmitting apparatus 130 may monitor current signals of multiple groups of chips through multiple groups of solder balls that may be electrically connected to the package 10, so as to locate failed chips and determine the order of failure of a plurality of chips. For example, when damage occurs to the chip in the package 10, additional losses may be increased in the circuit of the package 10, and as a result, the monitoring current I₀ may exceed a particular value (e.g., a threshold). In addition, different monitoring currents I₀ may represent different chips being damaged. That is, the different monitoring currents I₀ may represent different functional failures. Thus, the signal transmitting apparatus 130 may determine whether the plurality of chips in the package 10 are damaged by comparing the monitoring currents I₀ with the particular value (e.g., the threshold). When there are a plurality of chips in the package 10, the signal transmitting apparatus 130 may determine which chip of the plurality of chips is damaged through the monitoring currents I₀. However, the present disclosure is not limited thereto. In an exemplary embodiment, the signal transmitting apparatus 130 may input a segment of codes to the chip of the package 10, and the signal transmitting apparatus 130 may monitor whether the chip of the package 10 outputs the segment of codes as it is, thereby determining whether the chip inside the package 10 is damaged (e.g., has a functional failure).

The monitor 140 may be a display for displaying the strain value measured by the strainmeter 120 and/or the monitoring current I₀ obtained from the package 10 by the signal transmitting apparatus 130, but the present disclosure is not limited thereto. The monitor 140 may include a controller to control a force applied to the package 10, as well as, to control valves, movements of a movable carrier stage 214, a flexible pipe 215, and the like.

The load sensor 150 may measure the pressure applied to the package 10 by the pressure applying device. The pressure applying device may be and/or may include a device that may apply the static pressure. The pressure head 160 may be disposed below the load sensor 150. The pressure head 160 may be disposed between the load sensor 150 and the package 10, and may be in contact with the package 10. The force F applied to the package 10 by the pressure applying device may be applied to the package 10 through the load sensor 150 and the pressure head 160.

The method of monitoring the package 10 using the static monitoring apparatus 100 may be described as follows. Under the action of a static load (e.g., the action of a force F applied to the package 10 by the pressure applying device), the package 10 may be gradually deformed. When the deformation is relatively large, damage may begin to occur to the internal chip, and the package 10 may break when the deformation exceeds a limit of the package 10. The strainmeter 120 may be disposed on a lower surface of the package 10 and may collect strain values of the package 10 in real time during testing (e.g., while the static load is applied). The signal transmitting apparatus 130 may apply the voltage Vcc to the package 10 through a wire and the solder ball of the package 10 and may simultaneously and/or at a substantially similar time receive the monitoring current I₀ of the package 10 while the pressure applying device applies the pressure to the package 10. When damage occurs to the chip in the package 10, additional losses may be increased in the circuit of the package 10, and the monitoring current I₀ may exceed a particular value.

The number and arrangement of components of the static monitoring apparatus 100 shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Alternatively or additionally, a set of (one or more) components shown in FIG. 1 may be integrated with each other, and/or may be implemented as an integrated circuit, as software, and/or a combination of circuits and software.

FIG. 2 is a schematic diagram illustrating a monitoring apparatus for monitoring a threshold of functional failure of a package dynamically in real time, according to an exemplary embodiment of the present disclosure.

Referring to FIG. 2, a monitoring apparatus 200 may include a pressure applying device 210, an accommodation box 220, and a signal transmitting apparatus 230. The package 10 may be disposed in the accommodation box 220, and a strainmeter 240 may be disposed on the bottom surface of the package 10 in the accommodation box 220. The signal transmitting apparatus 230 may include and/or may be similar in many respects to the signal transmitting apparatus 130 described above with reference to FIG. 1, and may include additional features not mentioned above. Consequently, repeated descriptions of the signal transmitting apparatus 230 described above with reference to FIG. 1 may be omitted for the sake of brevity.

Although FIG. 2 does not illustrate that the signal transmitting apparatus 230 is electrically connected to the package 10, the signal transmitting apparatus 230 may likewise apply the voltage to the package 10 and receive the monitoring current I₀ from the package 10 in real time during testing. Differences from the foregoing embodiments are described mainly with reference to FIG. 2 below.

The pressure applying device 210 may include a gas generating device 20 and a conduit 211, and the gas generating device 20 may include a gas storage device 21 and a barometer 22. The gas storage device 21 may be and/or may include a high pressure gas cylinder loaded with a gas. A valve of the gas storage device 21 may control the opening and closing of the gas storage device 21. The barometer 22 may be disposed at the valve of the gas storage device 21, and may be configured to measure pressure intensity of the gas flowing out of the gas storage device 21. The conduit 211 may be connected (e.g., coupled) to the valve of the gas storage device 21 to form a path through which the gas may flow.

The pressure applying device 210 may also include a plurality of supports 212 for supporting and fixing the position of the conduit 211. One end of the conduit 211 may be connected to the valve of the gas storage device 21, and the other end thereof may be connected to a spherical hinge support 213. The pressure applying device 210 may also include the movable carrier stage 214. The other end of the conduit 211 may pass through the movable carrier stage 214 to be connected to the spherical hinge support 213. A surface of the accommodation box 220 may be disposed with a guide rail that may match with the movable carrier stage 214, so that the movable carrier stage 214 may move upward and backward, leftward and rightward, upward and downward along the guide rail. Thus, the conduit 211 may randomly move through the movable carrier stage 214.

The pressure applying device 210 may also include the flexible pipe 215. The flexible pipe 215 may be connected to the conduit 211 in a direction-changeable and interconnected manner through the above spherical hinge support 213, so that an angle between the flexible pipe 215 and the surface of the package 10 through the spherical hinge support 213 may be controllable. The flexible pipe 215 may be stretchable, a nozzle 216 may be disposed at an end of the flexible pipe 215, and by regulating a length of the flexible pipe 215, a frictionless contact between the nozzle 216 and the package 10 may be formed.

The conduit 211 may pass through the movable carrier stage 214, and the movable carrier stage 214 may randomly move along a guide rail of the accommodation box 220, so that the position of the movable carrier stage 214 may be adjusted. The flexible pipe 215 may be stretchable and flexible, such that, by moving and adjusting the movable carrier stage 214 and the flexible pipe 215, the nozzle 216 may form an arbitrary impact angle with the package 10. Consequently, the package 10 may be impacted at multiple angles by the nozzle 216. That is, the nozzle 216 may perform a multi-angle dynamic impact on the package 10.

In an embodiment, the valve of the gas storage device 21 may be and/or may include an electromagnetic valve, configured to control the flow of gas flowing out of the gas storage device 21. Thus, the monitoring apparatus 200 may realize the effect of comprehensively assessing the impact resistance characteristics of the package 10 from multiple angles.

The pressure sensor 250 may be disposed at the nozzle 216, to monitor and collect the force F applied to the package 10 by the pressure applying device 210. A tempered glass plate may constitute a box body of the accommodation box 220. In an embodiment, the tempered glass plate may include installation holes on that may allow the conduit 211 to pass through. The guide rail may be installed on a surface of the tempered glass plate. The space realized by the tempered glass plate may be used to prevent the external environment from influencing the monitoring of the package by the dynamic monitoring apparatus through the gas.

Although not shown in FIG. 2, the monitoring apparatus 200 may include the monitor 140 as described in FIG. 1.

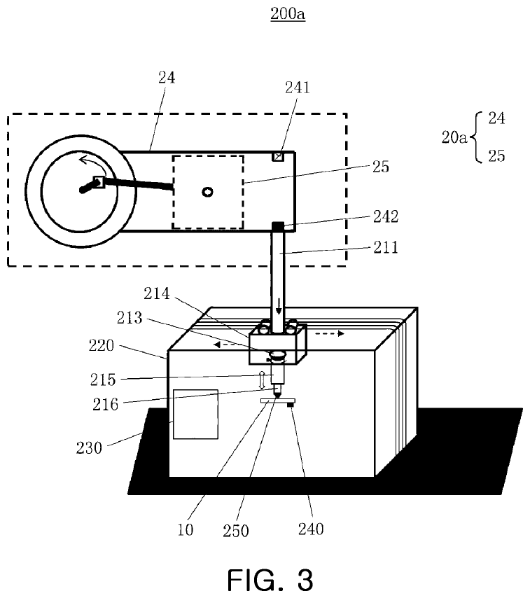

In an exemplary embodiment, the high pressure gas may be provided by the gas storage device as the high pressure gas cylinder. However, the present disclosure is not limited thereto. For example, the high pressure gas may be provided by a gas generating device as described with reference to FIG. 3.

The number and arrangement of components of the monitoring apparatus 200 shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Alternatively or additionally, a set of (one or more) components shown in FIG. 2 may be integrated with each other, and/or may be implemented as an integrated circuit, as software, and/or a combination of circuits and software.

FIG. 3 is a schematic diagram illustrating a monitoring apparatus for monitoring a threshold of functional failure of a package dynamically in real time, according to another exemplary embodiment of the present disclosure. The architecture and functionality of the monitoring apparatus 200a depicted in FIG. 3 may be similar in many respects to the architecture of the monitoring apparatus 200 described above with reference to FIG. 2, and may include additional features not mentioned above. For example, the gas generating device 20a may be different from the gas generating device 20 described with reference to FIG. 2. Repeated descriptions of the monitoring apparatus 200a described above with reference to FIG. 2 may be omitted for the sake of brevity.

The gas generating device 20a may include a cylinder 24 and a piston 25. The cylinder 24 may include an intake port 241 and an exhaust port 242 disposed on an upper surface and a lower surface of the cylinder 24, respectively. The piston 25 may be disposed in the cylinder 24 and may be configured to compress the gas in the cylinder 24. The external gas may enter into a cavity of the cylinder 24 from the intake port 241, and may be discharged out of the exhaust port 242, after being compressed via a reciprocating motion of the piston 25, to enter into the conduit 211.

In the exemplary embodiment of the present disclosure, the package 10 may not move (e.g., be in a fixed location and/or position), the nozzle 216 may be fixed on the stretchable and flexible pipe 215, and thus, a dynamic impact assessment on the package 10 from multiple angles may be performed by moving and/or adjusting positions of the movable carrier stage 214 and the flexible pipe 215.

For example, when conducting a static monitoring on the package 10, the signal transmitting apparatus 130 may apply a voltage to the package 10, and monitor output currents at different positions, thereby realizing the effect of spot monitoring the chip inside the package 10. Alternatively or additionally, the static monitoring of the package 10 may include, but may not be limited to, three-point bend testing (3PB), four-point bend testing (4PB), point pressure testing, and the like.

Although the present disclosure has been shown and described with reference to particular embodiments, it may be understood by those skilled in the art that various changes in form and details may be made herein without departing from the spirit and scope of the present disclosure as defined by the claims and equivalents thereof.

What is claimed is:

1. A monitoring apparatus for a package, comprising:
a pressure applying device configured to apply a pressure to the package;
a sensor configured to measure the pressure applied to the package by the pressure applying device; and
a signal transmitting apparatus electrically coupled to the package and configured to:
input an input signal to a chip of the package;
receive an output signal from the package in real time; and
monitor a damage of the chip of the package in real time while the pressure applying device applies the pressure to the package.

2. The monitoring apparatus of claim 1, further comprising:
a strainmeter disposed on a lower surface of the package and configured to measure a strain value of the package.

3. The monitoring apparatus of claim 1, wherein the pressure applying device comprises a conduit and a gas generating device configured to provide a high pressure gas, and
wherein a first end of the conduit is coupled to the gas generating device and configured to transmit the high pressure gas.

4. The monitoring apparatus of claim 3, further comprising:
an accommodation box configured to accommodate the package,
wherein a surface of the accommodation box comprises a guide rail, and
wherein the pressure applying device further comprises a movable carrier stage, the movable carrier stage being movable along the guide rail of the accommodation box, and the conduit passing through the movable carrier stage.

5. The monitoring apparatus of claim 4, wherein the pressure applying device further comprises a flexible pipe, and
wherein a second end of the conduit is coupled to an end of the flexible pipe in a direction-changeable and interconnected manner.

6. The monitoring apparatus of claim 5, wherein the conduit is coupled to the flexible pipe through a spherical hinge support.

7. The monitoring apparatus of claim 6, wherein the gas generating device comprises a gas storage device configured to store the high pressure gas.

8. The monitoring apparatus of claim 7, wherein the gas storage device comprises an electromagnetic valve.

9. The monitoring apparatus of claim 6, wherein the gas generating device comprises:
a cylinder;
an intake port disposed on an upper surface of the cylinder;
an exhaust port disposed on a lower surface of the cylinder; and
a piston disposed in the cylinder and configured to compress a gas in the cylinder.

10. The monitoring apparatus of claim 9, wherein the gas generating device is further configured to:
provide an external gas enters into a cavity of the cylinder through the intake port compress the external gas via a reciprocating motion of the piston; and
discharge compressed gas out of the cylinder from the exhaust port, to enter into the conduit.
